(19) United States
(12) Patent Application Publication
(10) Pub. No.: US 2007/0190328 A1
(43) Pub. Date: Aug. 16, 2007

(54) Modification

(75) Inventors: Russell Paul Cowburn, London (GB); Colm Faulkner, Bettystown (IE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: INGENIA HOLDINGS (U.K.) LIMITED, London (GB)

(21) Appl. No.: 11/611,692

(22) Filed: Dec. 15, 2006

Related U.S. Application Data
(60) Provisional application No. 60/750,865, filed on Dec. 16, 2005.
(60) Provisional application No. 60/824,551, filed on Sep. 5, 2006.

(30) Foreign Application Priority Data
Dec. 16, 2005 (GB) 0525648.2
Sep. 5, 2006 (GB) 0617481.7

(51) Int. Cl. B05D 5/12; B05D 3/00; C23C 14/00; B32B 17/10

(52) U.S. Cl. 428/409; 427/523; 427/532; 427/127

(57) ABSTRACT

A structure having a thin film magnetic layer sandwiched between a substrate and a surface layer is bombarded with ions. The ions impact the surface layer and cause atoms from the surface layer to be moved to implant into the magnetic layer. Thereby the magnetic characteristics of a region of the magnetic layer are altered, modified or destroyed.

### RELATED APPLICATIONS

This application claims priority to and incorporates by reference U.S. provisional application No. 60/750,865 filed on Dec. 16, 2005, U.S. provisional application No. 60/824,551 filed on Sep. 5, 2006, Great Britain patent application number GB 0525648.2 filed on Dec. 16, 2005, and Great Britain patent application number GB 0617481.7 filed on Sep. 5, 2006.

### BACKGROUND OF THE INVENTION

The present invention relates to modification, and in particular but not exclusively to use of an ion beam in the modification of magnetic films.

In the field of magnetic devices such as magnetic storage (such as memories such as RAMs and magnetic storage media such as hard disk drives) or magnetic field sensors, it is known to use materials exhibiting perpendicularly magnetised anisotropy (PMA) for manufacture of thin film magnetic layers. In materials exhibiting PMA properties, a thin film (typically of the material) will have a magnetisation direction which is dependent upon a surface layer thereupon. With no surface layer, or a surface layer of a material which does not cause PMA behaviour, the magnetisation direction will be parallel to the plane of the thin film. With a surface layer of a suitable material, the magnetisation direction alters by 90 degrees to be perpendicular to the plane of the thin film.

Conventional systems for utilising the PMA effect of thin film magnetic layers create areas where PMA is in effect and areas where it is not. This is done by, for example, disturbing the boundary between the thin film and the surface layer using a bombardment of helium ions to create a situation where most of the atoms at the boundary are surrounded by random selections of atoms from both the thin film and the surface layer and as such behave as though they were in the centre of a mass of the PMA material, and hence the PMA effect does not occur. Such an approach is detailed by C. Chappert et al in their paper “Planar Patterned Magnetic Media Obtained by Ion Irradiation” published in Science Vol. 280, pages 1919-1922, 19 Jun. 1998. This technology was applied to hard disk media by D. Weller et al in their paper “Ion induced magnetization reorientation in CO/Pt multilayers for patterned media” published in the Journal of Applied Physics Vol. 87, No. 9, 1 May 2000.

Another known technique for creating areas of magnetically active and inactive material in a magnetic layer is to implant Gallium ions into the magnetic layer in areas where the magnetic effect is not desired. The implanted ions interfere with the magnetic layer such that magnetisation is destroyed. This technique includes use of a non-magnetic over-layer over the magnetic layer to prevent sputtering of the magnetic layer. This is described in W. M. Kaminsky et al in their paper “Patterning ferromagnetism in Ni₈₀Fe₂₀ films via Ga⁺ ion irradiation” published in Applied Physics Letters, Vol. 78, No. 11, 12 Mar. 2001.

It is also known to perform these techniques using both focussed an unfocussed ion beams. The focussed beam techniques are mostly limited to laboratory-based applications due to the low speed of the procedures which make commercial exploitation prohibitively expensive for most purposes. The unfocussed beam techniques are much faster but are not able to provide the same resolution for pattern production as focussed beam techniques.

### SUMMARY OF THE INVENTION

The present invention has been made, at least in part, in consideration of problems and drawbacks of conventional systems.

Viewed from a first aspect, the present invention provides a method for manufacturing magnetic devices. According to the method, a structure having a thin film magnetic layer sandwiched between a substrate and a surface layer is bombarded with ions. The ions impact the surface layer and cause atoms from the surface layer to be moved to implant into the magnetic layer. Thereby the magnetic characteristics of a region of the magnetic layer are altered. This manufacture process requires a dose up to twenty times lower than conventional systems such that ion beam milling for creation of magnetic devices can be sped up twentyfold.

The ion bombardment can be restricted to areas of the device by use of an applied mask of ion resistive material to areas where no magnetisation alteration is required, or by the use of a focussed ion beam which is targeted only at the areas where the magnetisation alteration is desired.

In one embodiment, the implanted atoms in the magnetic layer cause destruction of the magnetic properties of the region of magnetic material by poisoning of the magnetic material. In another embodiment, where a lower ion dose is applied, the implanted atoms in the surface layer modify the coercivity or the anisotropy of the region of the magnetic material.

Viewed from another aspect, the present invention provides a patterned magnetic device. The device comprises a thin film magnetic layer sandwiched between a substrate and a surface layer. The magnetic layer has regions in which the magnetisation has been altered by implantation thereinto of atoms from the surface layer caused by subjection of the surface layer to ionic bombardment. Thus a patterned magnetic device created using a low ionic bombardment dose can be provided for use in magnetic memories, magnetic field sensors and the like.

In some embodiments, the magnetic material is one of cobalt, nickel, iron, a cobalt-iron alloy, a nickel-iron alloy, an iron-silicon alloy, and a cobalt-iron-boron alloy. In some embodiments, the thin film layer of magnetic material is between 2 nm and 5 nm.

In some embodiments, the surface layer comprises a non-magnetic element. In some embodiments, the non-magnetic element is one of gold, aluminium, rubidium, platinum, silver, boron, tantalum, chromium or copper. In some embodiments, the surface layer has a thickness in the range 5-15 nm.

In some embodiments, the ions are noble gas ions or gallium ions. In some embodiments, the ions have an average energy in the range 200 eV to 1 MeV. In other embodiments, the ions have an average energy in the range 200 eV to 50 KeV.

In some embodiments, the magnetic material is formed on a substrate. In some embodiments, the substrate is one of silicon, silicon dioxide, gallium arsenide, a polyamide or PET (Polyethylene terephthalate).

In some embodiments, the ion bombardment is performed using an unfocussed ion beam. In other embodiments, the ion bombardment is performed using a focussed ion beam.

In some embodiments, a mask is applied to the surface layer to prevent the creation of areas of altered magnetisation outside of a desired area of the magnetic material.

In some embodiments, altering the magnetisation of an area within the magnetic material comprises destroying the magnetisation.

In some embodiments, the surface layer atoms displaced into the magnetic material cause poisoning of the magnetic material.

In some embodiments, the magnetic device further comprises a second thin film magnetic layer and a thin film inter-layer sandwiched between the magnetic layer and the substrate. In some embodiments, the second magnetic layer exhibits perpendicularly magnetised anisotropy. In some embodiments the second magnetic layer comprises one of cobalt, nickel, iron, a cobalt-iron alloy, a nickel-iron alloy, an iron-silicon alloy, and a cobalt-iron-boron alloy. In some embodiments, the second magnetic layer has a thickness of between 2 nm and 5 nm.

In some embodiments, the inter-layer comprises ruthenium, iridium or another platinum group metal.

In some embodiments, the magnetic device is one of a magnetic memory and a magnetic field sensor Viewed from another aspect, the present invention provides a magnetic device comprising a thin film magnetic layer on a substrate, the magnetic layer having a surface layer formed thereupon and having regions therein where a magnetisation of the magnetic layer has been altered by atoms moved into the magnetic layer from the surface layer.

In some embodiments, at least one region has a destroyed magnetisation. In some embodiments, at least one region has an altered anisotropy. In some embodiments, at least one region has an altered coercivity.

In some embodiments, the device further comprises a second thin film magnetic layer and an inter-layer sandwiched between the magnetic layer and the substrate.

### BRIEF DESCRIPTION OF THE FIGURES

Specific embodiments of the present invention will now be described by way of example only, with reference to the accompanying figures in which:

FIGS. 1a-h show schematic representations of an example of a manufacture process for a magnetic device;

FIGS. 2a and 2b show a simplified schematic representation of atom displacement in the magnetic device of FIG. 1.

FIG. 3 shows a schematic representation of an optional additional step in the process of FIG. 1;

FIGS. 4a-j show schematic representations of an example of a manufacture process for a synthetic anti-ferromagnetic device;

FIG. 5 shows a schematic representation of an optional additional step in the process of FIG. 4;

FIG. 6 shows a schematic representation of an alternative example of a manufacture process for a synthetic anti-ferromagnetic device;

FIG. 7 shows experimental data demonstrating the alteration of the coercivity and/or anisotropy of a magnetic device by ion bombardment;

FIG. 8 shows experimental data demonstrating the alteration of the coercivity and/or anisotropy of a magnetic device by ion bombardment;

FIG. 9 shows experimental data demonstrating the alteration of the coercivity and/or anisotropy of a magnetic device by ion bombardment; and

FIG. 10 shows experimental data demonstrating the alteration of the coercivity and/or anisotropy of a magnetic device by ion bombardment.

While the invention is susceptible to various modifications and alternative forms, specific embodiments are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the spirit and scope of the present invention as defined by the appended claims.

### DESCRIPTION OF PARTICULAR EMBODIMENTS

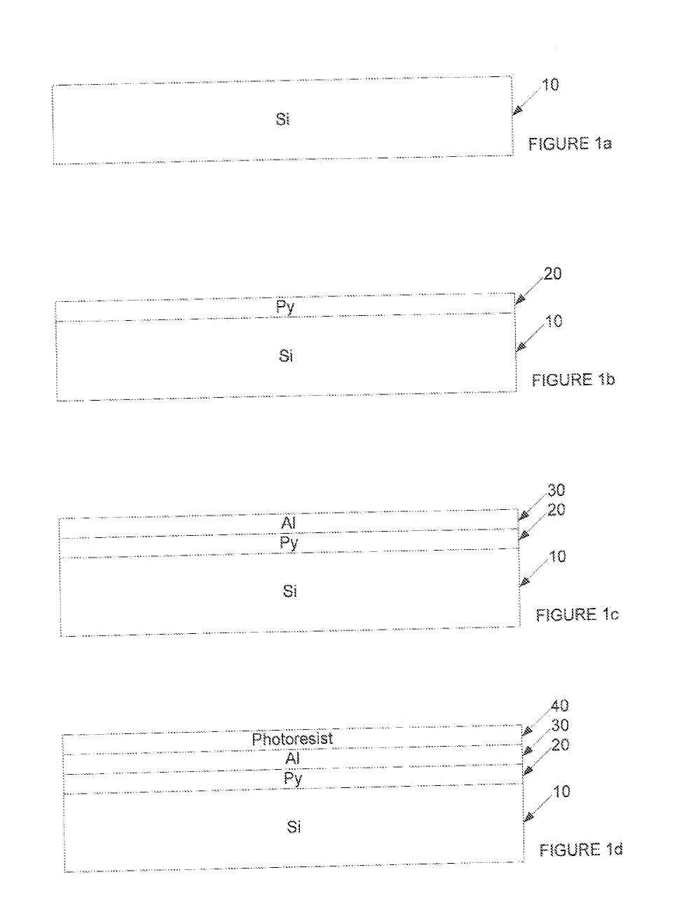

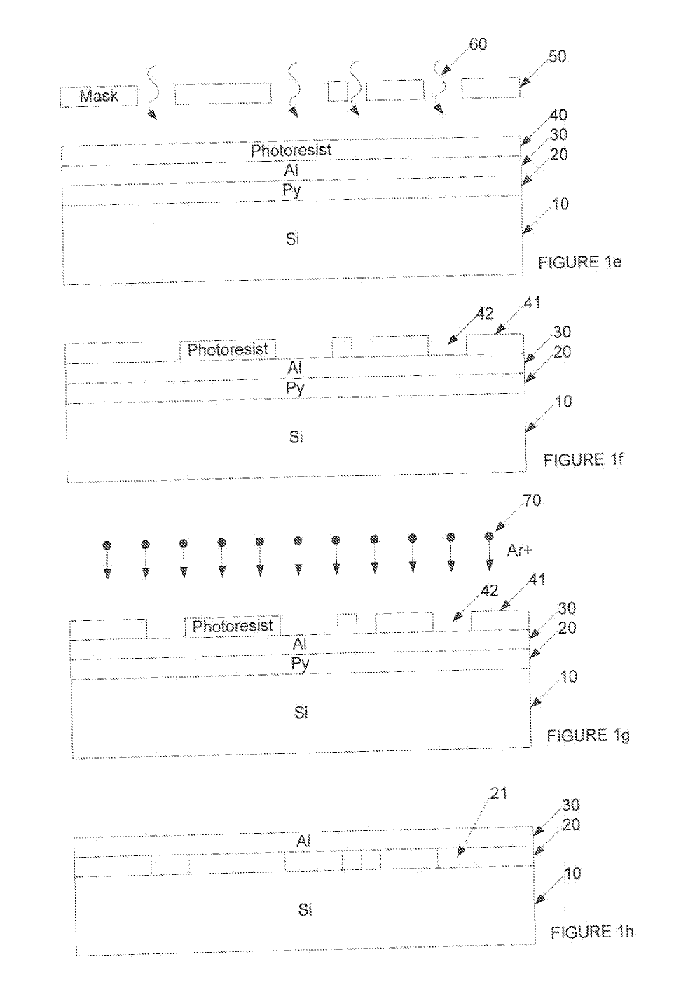

An example of a structure of patterned ferromagnetic material, and a method of manufacturing same will be described with reference to FIG. 1.

First, a substrate 10 of silicon is provided as shown in FIG. 1a. Onto this substrate 10, a thin film 20 of permalloy (Ni₈₀Fe₂₀) is deposited by thermal evaporation, spatter deposition or electro-deposition as shown in FIG. 1b. The thin film 20 of permalloy has, in the present example, a thickness in the range of 0.5-10 nm. A thickness in the range 2-5 nm may produce improved results.

Then, over the thin film permalloy layer 20, a surface layer 30 of Aluminium is deposited using thermal evaporation or spatter deposition as shown in FIG. 1c. This surface layer 30 has, in the present example a thickness of between one and three times the thickness of the thin film permalloy layer 20. Thus a thickness in the range 5-15 nm may produce good results.

At this stage, the permalloy layer 20 has a substantially uniform magnetisation parallel to the plane of the layer. This is the case across the whole of the structure. Thus, in order to create a patterned magnetic structure, further steps are performed to alter the magnetic filed on a localised basis.

On top of the surface layer 30, a layer of a suitable photolithography photoresist 40 is deposited by spin coating as shown in FIG. 1d. The photoresist 40 is then exposed to light 60 through a mask 50 as shown in FIG. 1e before being developed using a proprietary developer appropriate to the photolithography resist to create a pattern in the photoresist layer 40, as illustrated in FIG. 1f. The patterned photoresist layer includes areas 41 where the photoresist remains and gaps therebetween 42.

Having thereby created a photoresist pattern over the surface layer 30, the structure is then exposed to argon ions 70 as shown in FIG. 1g. In the present example, ions having an average energy of 30 KeV are used. The ions are deflected from the structure and/or absorbed by the photoresist areas 41 but, where the gaps 42 exist, the ions are incident with the aluminium surface layer 30. These incident ions collide with atoms in the aluminium surface layer 30 and cannon those atoms into the thin film permalloy layer 20. Each incident ion displaces a large number of atoms from the surface layer, a significant proportion of which become moved into the magnetic material in layer 20. In one example, 1 incident ion with an energy of 30 KeV displaces up to 800 atoms in the aluminium surface layer. Thereby, the cannoned atoms poison the ferromagnetic layer 20 in the regions 21 such that the ferromagnetism of the layer 20 is destroyed in the regions 21 as shown in FIG. 1h. Following the irradiation of the device with the ions, the photoresist 40 can be stripped from the device to leave a flat upper surface using acetone or other suitable stripping agent.

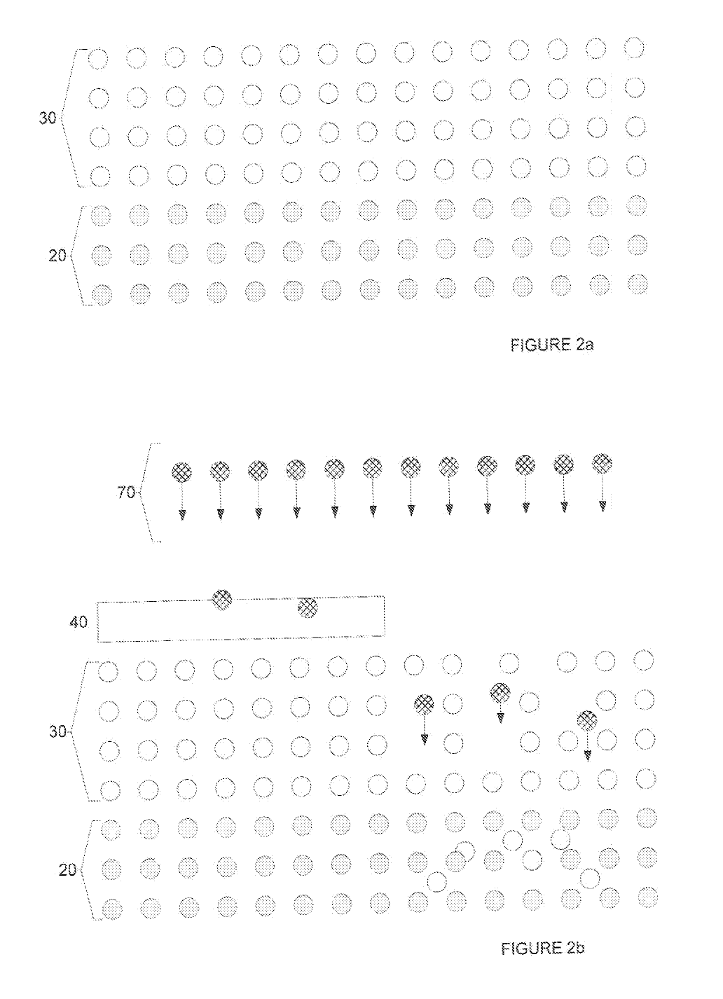

A simplified schematic view of this process is shown in FIGS. 2a and 2b. In FIG. 2a, there are represented a number of atoms in the permalloy layer 20 and a number of atoms in the aluminium surface layer 30. In FIG. 2b, part of the surface layer 30 is covered by a layer of photoresist 40. The structure is then bombarded with Argon ions 70. Where the photoresist 40 covers the surface layer 30, the Argon ions become embedded into the photoresist 40. Where no photoresist is present, the Argon ions impact the surface layer, becoming embedded therein. In the process, the high energy Argon ions displace aluminium atoms from the surface layer, causing some aluminium ions to be pushed into the permalloy layer. The presence of the aluminium atoms in the permalloy layer poisons the permalloy such that it loses its ferromagnetic properties. Thereby a non-magnetic region 21 is created.

In the context of the present example, the implantation of the surface layer atoms into the magnetic layer causes localised poisoning of the magnetic layer once the concentration of implanted ions in a given region reaches approximately 5% by atomic mass. More details of impurity amounts required for poisoning of ferromagnets may be found in Richard M. Bosworth, “Ferromagnetism”, IEEE Press 1993, ISBN 0-7803-1032-2. For example, to poison Ni₇₈Fe₁₂ (a permalloy) which normally has a Curie temperature of 540° with Molybdenum, adding 2-3% Molybdenum lowers the curie temperature by approximately 100°, with a total of 14% Molybdenum being required to reduce the Curie temperature to zero.

Although it has been described above that the substrate is silicon, other substrate materials could be used, such as silicon dioxide (SiO₂), Gallium Arsenide, Polyamides or PET.

Although it has been described above that the thin film layer of magnetic material is permalloy, other materials can be used. Other suitable materials include, for example, cobalt, nickel, iron, cobalt-iron alloys, nickel-iron alloys, iron-silicon alloys, and cobalt-iron-boron alloys. For more details of ferromagnetic materials see Richard M. Bosworth, “Ferromagnetism”, IEEE Press 1993, ISBN 0-7803-1032-2.

Although it has been described above that the surface layer is aluminium, other materials could be used. One group of suitable materials are the “noble metals” (silver, gold, platinum, palladium, rhodium, ruthenium, iridium and osmium). Other suitable materials include boron, tantalum, chromium and copper. A property shared by these materials is that the material can disrupt magnetisation within a ferromagnetic material by breaking up the crystal structure of the ferromagnetic material. Materials which are less suitable are materials which are not solid at room temperature, materials which oxidise easily and materials which are difficult to deposit in thin films.

Although it has been described above that the ions used are argon ions, other materials could be used. For example, ions of any noble gas (helium, neon, argon, krypton, xenon and radon) could be used.

Although it has been described above that the ions have an average energy of 30 KeV, other ionic energies could be used. Ionic energies in the range from 200 eV to mega-eV can be used. For improved performance, energies in the range of 1 KeV to 50 KeV can be used.

Although the above-described example relates to use of a photolithographic mask and an unfocussed ion beam, the method embodied therein can also be applied to focussed ion beam milling applications. Thus a device may be fabricated without the use of photoresist, and a focussed ion beam may be used for the patterning of the ferromagnetic layer. The pattern resolution in each case is the maximum resolution achievable using the respective milling technique. For example, most commercial fabrication systems using unfocussed ion milling and a photolithographic mask achieve a resolution of up to 90 nm, although 110 nm and 130 nm processes are also commonly used. In laboratory based focussed ion beam processes, resolutions of up to 10 nm can be obtained.

Thus there has now been described a system and method for producing a patterned magnetic device. Such a device can be made using this system and method using an ionic irradiation dose up to twenty times less than the dose required for similar patterning of a magnetic device by conventional systems. Therefore, by maintaining the dosage level used in conventional systems, device manufacture can be sped up considerable as the milling step takes only one twentieth of the time of a conventional process. Thus, in addition to the speed and cost benefits associated with increasing the efficiency of traditional commercial applications of unfocussed ion beam milling, the present system also makes focussed ion beam milling (which is traditionally only used for laboratory purposes) much more commercially viable.

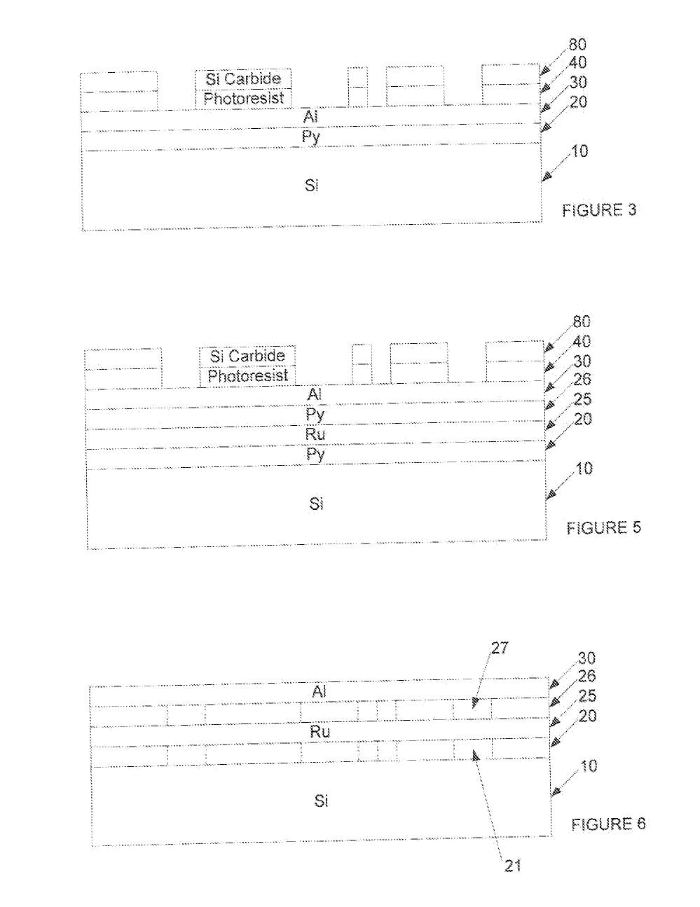

With reference to FIG. 3, there will now be described an optional additional step for the fabrication process described with reference to FIGS. 1 above. Following deposition of the photoresist 40, and exposure thereof to light through a mask 50, and subsequent development of the photoresist to create the pattern of photoresist on the surface layer 30, but prior to the exposure to ions, a layer of silicon carbide can be selectively deposited by CVD (chemical vapour deposition) on the remaining photoresist. This additional layer provides further defence against the incoming ions in areas where it is desired that the magnetic material is not poisoned. By means of this modified method, accidental milling of areas in which no milling is desired can be further resisted.

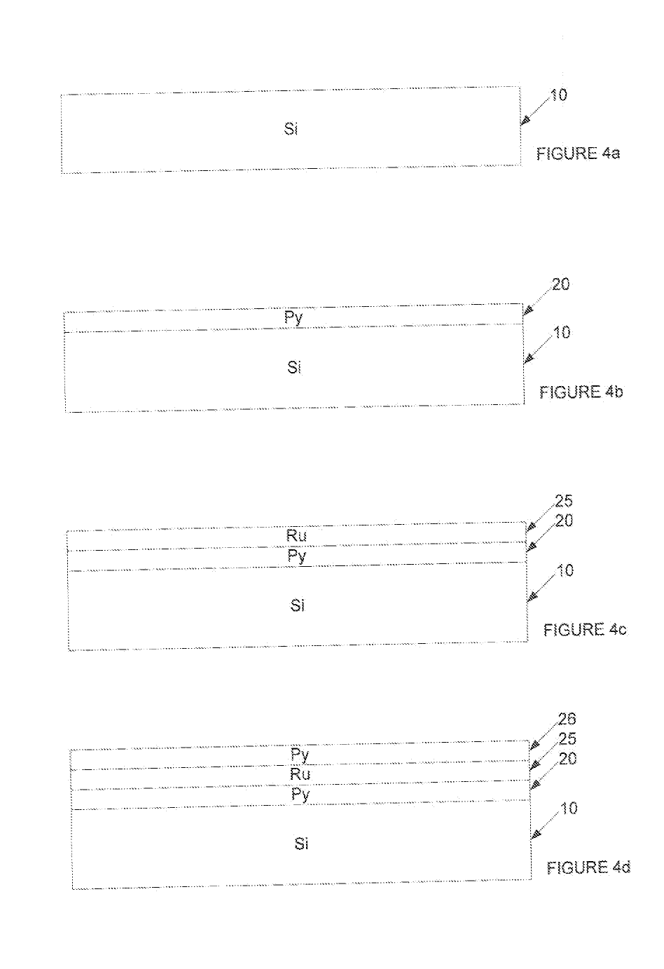

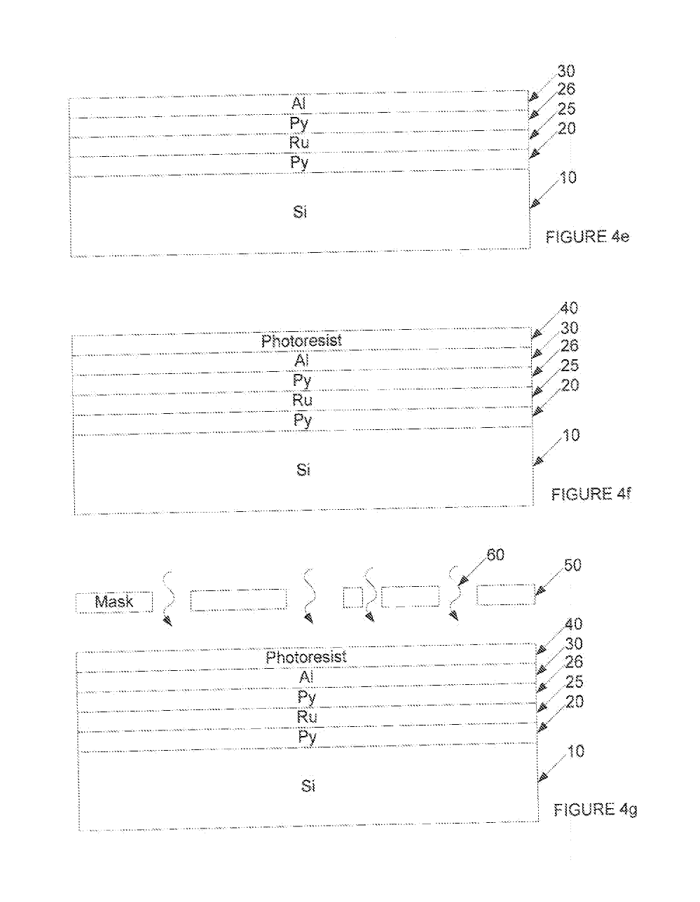

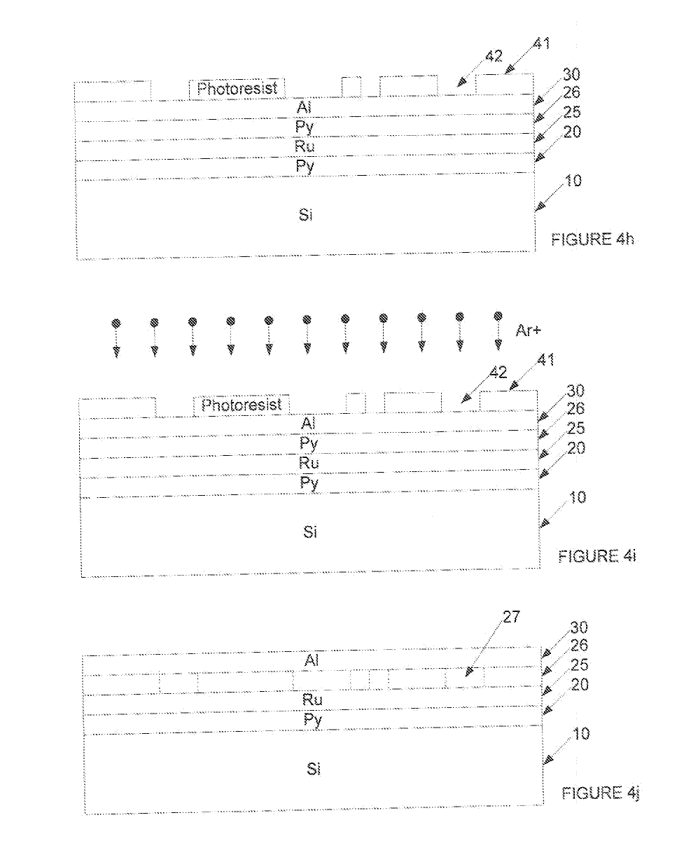

An example of a structure of patterned synthetic anti-ferromagnet, and a method of manufacturing same will be described with reference to FIG. 4.

First, a substrate 10 of Silicon is provided as shown in FIG. 4a. Onto this substrate 10, a thin film 20 of permalloy (Ni₈₀Fe₂₀) is deposited by thermal evaporation, sputter deposition or electro-deposition as shown in FIG. 4b. The thin film 20 of permalloy has, in the present example, a thickness in the range of 0.5-10 nm. A thickness in the range 2-5 nm may produce improved results.

Over the permalloy layer 20, a layer 25 of ruthenium is deposited by sputter deposition as shown in FIG. 4c. The layer 25 of ruthenium has a thickness in the range of 0.2-1.5 nm. Then, over the ruthenium layer 25, a further layer 26 of permalloy is deposited by thermal evaporation or sputter deposition as shown in FIG. 4d. This layer also has a thickness in the range of 0.5-10 nm. A thickness in the range 2-5 nm may produce improved results.

Then, over the thin film permalloy layer 26, a surface layer 30 of Aluminium is deposited using thermal evaporation or sputter deposition as shown in FIG. 4e. This surface layer 30 has, in the present example a thickness of between one and three times the thickness of the each of the thin film permalloy layers 20 and 26. Thus a thickness in the range 5-15 nm may produce good results.

At this stage, the permalloy layers 20 and 26 have mutually opposed magnetisations parallel to the plane of the layer (this phenomenon is often known as “synthetic antiferromagnetism”. This is caused by the interaction between the thin films of permalloy through the interlayer spacer of ruthenium. This is the case across the whole of the structure. Thus, in order to create a patterned magnetic structure, further steps are performed to alter the magnetic filed on a localised basis.

On top of the surface layer 30, a layer of a suitable photo lithography photoresist 40 is deposited by spin coating as shown in FIG. 4f. The photoresist 40 is then exposed to light 60 through a mask 50 as shown in FIG. 4g before being developed using a proprietary developer appropriate to the photo lithography resist to create a pattern in the photoresist layer 40, as illustrated in FIG. 4h. The patterned photoresist layer includes areas 41 where the photoresist remains and gaps therebetween 42.

Having thereby created a photoresist pattern over the surface layer 30, the structure is then exposed to argon ions 70 as shown in FIG. 4i. In the present example, ions having an average energy of 30 KeV are used. The ions are deflected from the structure and/or absorbed by the photoresist areas 41 but, where the gaps 42 exist, the ions are incident with the aluminium surface layer 30. These incident ions collide with atoms in the aluminium surface layer 30 and cannon those atoms into the upper thin film permalloy layer 26. Each incident ion displaces a large number of atoms from the surface layer, a significant proportion of which become moved into the magnetic material in layer 26. In one example, 1 incident ion with an energy of 30 KeV displaces up to 800 atoms in the aluminium surface layer. Thereby, the cannoned atoms poison the ferromagnetic layer 26 in the regions 27 such that the ferromagnetism of the layer 26 is destroyed in the regions 27 as shown in FIG. 4j. Following the irradiation of the device with the ions, the photoresist 40 can be stripped from the device using acetone or other appropriate stripping agent to leave a flat upper surface.

Due to the interaction of the layers within a synthetic anti-ferromagnet, the poisoning of the layer 26 ion the regions 27 causes the magnetisation of the underlying layer 20 to be disrupted. Therefore, in the present example, the under layer 20 of permalloy has regions therein corresponding in position to the regions 27 in which the magnetisation is disrupted to produce a non-magnetic region in one or both layers of the synthetic anti-ferromagnet.

In the context of the present example, the implantation of the surface layer atoms into the magnetic layer causes localised poisoning of the magnetic layer once the concentration of implanted ions in a given region reaches approximately 5% by atomic mass. More details of impurity amounts required for poisoning of ferromagnets may be found in Richard M. Bosworth, “Ferromagnetism”, IEEE Press 1993, ISBN 0-7803-1032-2. For example, to poison Ni₇₈Fe₁₂ (a permalloy) which normally has a Curie temperature of 540° with Molybdenum, adding 2-3% Molybdenum lowers the curie temperature by approximately 100°, with a total of 14% Molybdenum being required to reduce the Curie temperature to zero.

Although it has been described above that the substrate is silicon, other substrate materials could be used, such as silicon dioxide (SiO₂), Gallium Arsenide, Polyamides or PET.

Although it has been described above that the thin film layers of magnetic material are permalloy, other materials can be used. Other suitable materials include, for example, cobalt, nickel, iron, cobalt-iron alloys, nickel-iron alloys, iron-silicon alloys, and cobalt-iron-boron alloys. For more details of ferromagnetic materials see Richard M. Bosworth, “Ferromagnetism”, IEEE Press 1993, ISBN 0-7803-1032-2.

Although it has been described that the sandwiched layer 25 between the two layers of magnetic material is ruthenium other materials can be used, such as Iridium or other platinum group metals.

Although it has been described above that the surface layer is aluminium, other materials could be used. One group of suitable materials are the “noble metals” (silver, gold, platinum, palladium, rhodium, ruthenium, iridium and osmium). Other suitable materials include boron, tantalum, chromium and copper. A property shared by these materials is that the material can disrupt magnetisation within a ferromagnetic material by breaking up the crystal structure of the ferromagnetic material. Materials which are less suitable are materials which are not solid at room temperature, materials which oxidise easily and materials which are difficult to deposit in thin films.

Although it has been described above that the ions used are argon ions, other materials could be used. For example, ions of any noble gas (helium, neon, argon, krypton, xenon and radon) could be used.

Although it has been described above that the ions have an average energy of 30 KeV, other ionic energies could be used. Ionic energies in the range from 200 eV to mega-eV can be used. For improved performance, energies in the range of 1 KeV to 50 KeV can be used.

Although the above-described example relates to use of a photolithographic mask and an unfocussed ion beam, the method embodied therein can also be applied to focussed ion beam milling applications. Thus a device may be fabricated without the use of photoresist, and a focussed ion beam may be used for the patterning of the ferromagnetic layer. The pattern resolution in each case is the maximum resolution achievable using the respective milling technique. For example, most commercial fabrication systems using unfocussed ion milling and a photolithographic mask achieve a resolution of up to 90nm, although 110 nm and 130 nm processes are also commonly used. In laboratory based focussed ion beam processes, resolutions of up to 10 nm can be obtained.

As an alternative to using a photoresist with a mask and light exposure to create the resist pattern prior to ion exposure, a resist such as PMMA (polymethylmethacrylate) can be used. Such a resist can be patterned using an electron beam (normally a focussed beam without a mask). Following exposure to the electron beam, the PMMA resist can be developed using a suitable developer such as MIBK (methylisobutylketone) dissolved in propenol at a 1:3 ratio. In one example, a development time of 30 seconds can be used.

Thus there has now been described a system and method for producing a patterned synthetic anti-ferromagnet. Such a device can be made using this system and method using an ionic irradiation dose up to twenty times less than the dose required for similar patterning of a magnetic device by conventional systems. Therefore, by maintaining the dosage level used in conventional systems, device manufacture can be sped up considerable as the milling step takes only one twentieth of the time of a conventional process. Thus, in addition to the speed and cost benefits associated with increasing the efficiency of traditional commercial applications of unfocussed ion beam milling, the present system also makes focussed ion beam milling (which is traditionally only used for laboratory purposes) much more commercially viable.

With reference to FIG. 5, there will now be described an optional additional step for the fabrication process described with reference to FIGS. 4 above. Following deposition of the photoresist 40, and exposure thereof to light through a mask 50, and subsequent development of the photoresist to create the pattern of photoresist on the surface layer 30, but prior to the exposure to ions, a layer of silicon carbide can be selectively deposited by CVD (Chemical Vapour Deposition) on the remaining photoresist. This additional layer provides further defence against the incoming ions in areas where it is desired that the magnetic material is not poisoned. By means of this modified method, accidental milling of areas in which no milling is desired can be further resisted.

With reference to FIG. 6, there will now be described another alternative example of a method for producing a patterned synthetic anti-ferromagnet. In this example, the ions used to irradiate the device cause atoms from the surface layer 30 to cannon into the magnetic layer 26, thereby creating the non-magnetic regions 27. The cannoning effect can also cause surface layer atoms to cannon into corresponding parts of the lower magnetic layer 20 thereby creating non-magnetic regions 21. This in this example, both magnetic layers are disrupted due to poisoning of the magnetic material.

Thus there have now been described a variety of techniques for creation of patterned ferromagnetic devices.

Some experimental data showing the ion dose necessary to alter and/or completely destroy the magnetic properties of a ferromagnetic structure, for example in accordance with the above described steps of FIG. 1, 2, 3, 4, 5 or 6.

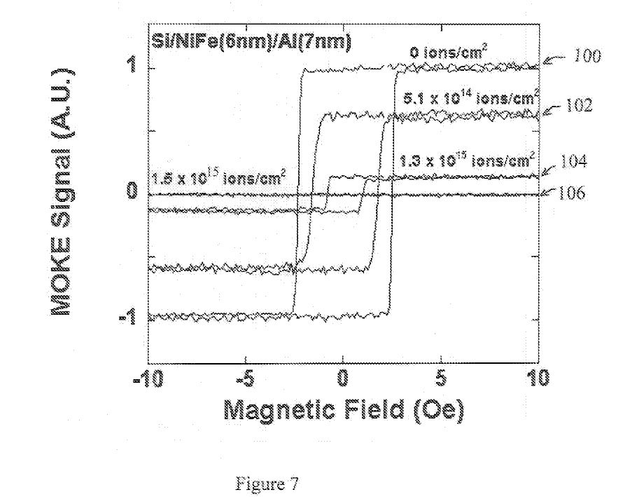

FIG. 7 shows example data for the gradual poisoning of a ferromagnetic structure such as may be produced in accordance with the steps of FIG. 1. The particular structure from which the test data were derived featured a silicon substrate having a 6 nm permalloy layer thereon, with an aluminium overlayer 7 nm thick.

FIG. 7 shows a plot of a measured MOKE (Magneto-Optic Kerr Effect) Signal from the ferromagnetic structure against applied magnetic field intensity (Oe). As can be seen from FIG. 7, with no ion exposure (trace 100), the structure maintains a full normal magnetic response. In this regard it is noted that, as expected, polarisation switching occurs at different applied field intensities.

When a low ion dose is applied (5.1×10¹⁴ ions/cm²) as depicted by trace 102, the measured MOKE signal has a lower intensity, indicating that curie temperature of the magnetic structure has been reduced. Also, the applied magnetic field intensity required to cause polarisation switching is reduced.

With a higher applied ion dose (1.3×10¹⁵ ions/cm²) as depicted by trace 104, the curie temperature of the magnetic structure is further reduced. Finally, once an ion dose of 1.5×10¹⁵ ions/cm² is applied, the magnetic structure has had its magnetic properties completely destroyed, such that the curie temperature has been reduced to zero. Where the curie temperature is reduced to zero, the anisotropy of the magnetic film is altered so as to reduce the magnetic filed effect in the magnetic layer, hence rendering it non-ferromagnetic. The interference of the surface layer ions cannoned into the magnetic layer interrupt the layer effects which cause interruptions in the magnetisation of the magnetic layer. Thus it is apparent that different ion doses cause different levels of alteration to the coercivity of the magnetic structure.

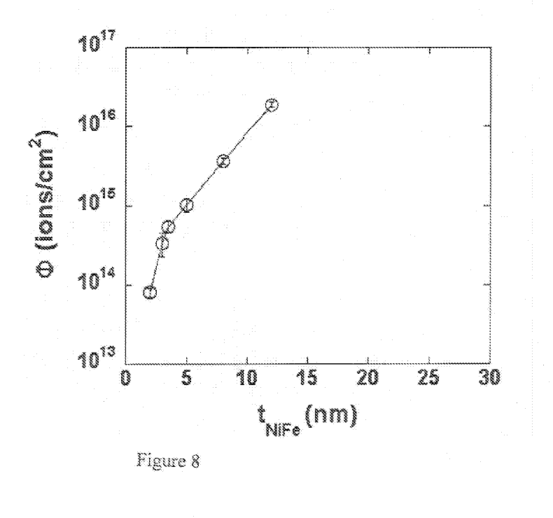

Another set of experimental data are shown in FIG. 8. In FIG. 8, a trace is plotted of the ion dose necessary to completely kill the ferromagnetism in a ferromagnetic structure, for example a structure in accordance with the above described steps of FIG. 1, 2, 3, 4, 5 or 6, for different permalloy film thicknesses. An aluminium overlayer of thickness 10 nm was used in all cases. As shown, where the permalloy layer thickness is only 2 nm, the ion dose required to kill the ferromagnetic properties of the structure is approximately 9×10¹³ ions/cm². As the permalloy layer thickness increases, the necessary ion dose increases, until at a permalloy layer thickness of approximately 13nm, the ion does required is around 3×10¹⁶ ions/cm². Thus it is apparent that different ion does cause different levels of alteration to the coercivity of the magnetic structure.

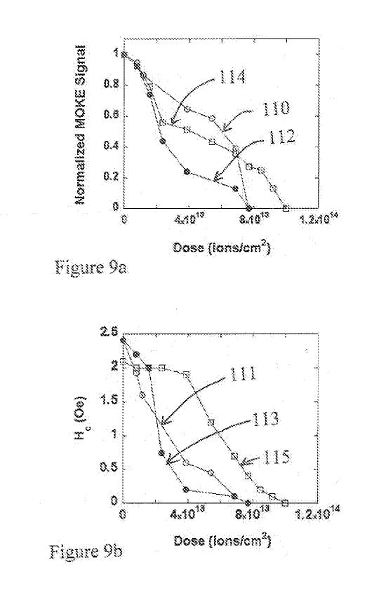

FIGS. 9a and 9b show the measured normalised MOKE signal and inherent field strength of various sample ferromagnetic structures, for example structures in accordance with the above described steps of FIG. 1, 2, 3, 4, 5 or 6, at various applied ion doses. In FIGS. 9a and 9b, all structures had a permalloy (Ni₈₀Fe₂₀) layer thickness of 2 nm and aluminium overlayer thicknesses of 4 nm (open circle—traces 110,111), 8 nm (closed circle—traces 112,113) and 12 nm (open square—traces 114,115). Thus the drop in ferromagnetic response for each structure with increasing applied ion dose can be seen. Thus it is apparent that different ion does cause different levels of alteration to the coercivity of the magnetic structure.

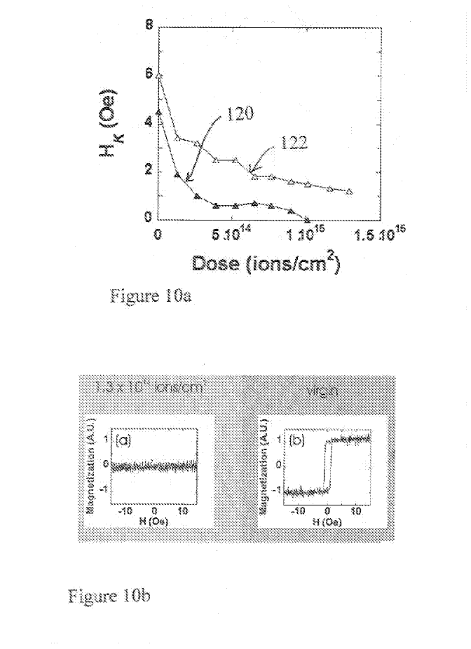

FIGS. 10a and 10b show further experimental data this time using a gold in place of aluminium for the overlayer. FIG. 10a shows the inherent magnetic field strength of various sample ferromagnetic structures, for example structures in accordance with the above described steps of FIG. 1, 2, 3, 4, 5 or 6, at various applied ion doses. In FIG. 10a, all structures had a gold 7 nm overlayer and permalloy layer thickness of 4 nm (closed triangle—trace 120) and 6 nm (open triangle—trace 122). Thus the drop in ferromagnetic response for each structure with increasing applied ion dose can be seen. Thus it is apparent that different ion does cause different levels of alteration to the coercivity of the magnetic structure.

FIG. 10b shows the measured magnetisation (Normalised MOKE signal) for a structure with a 2 nm permalloy layer with a 7 nm gold overlayer, before ion bombardment (“virgin”) and after ion bombardment of 1.3×10¹⁴ ions/cm².

Thus there have now been described a variety of processes and methods for creation of patterned magnetic devices such as may be used in magnetic memories or magnetic field sensors. The different techniques described in the above examples may be combined in any way to produce further examples and embodiments which lie within the spirit and scope of the present invention.

Although the embodiments above have been described in considerable detail, numerous variations and modifications will become apparent to those skilled in the art once the above disclosure is fully appreciated. It is intended that the following claims be interpreted to embrace all such variations and modifications as well as their equivalents.

1. A method for manufacture of a magnetic device, the method comprising:
bombarding a surface layer covering a thin film layer of magnetic material with ions to displace atoms from the surface layer into the magnetic material to alter the magnetisation of an area within the magnetic material.

2. The method of claim 1, wherein the magnetic material is one of cobalt, nickel, iron, a cobalt-iron alloy, a nickel-iron alloy, an iron-silicon alloy, and a cobalt-iron-boron alloy.

3. The method of claim 1, wherein the surface layer comprises a non-magnetic element.

4. The method of claim 1, wherein the ions are noble gas ions or gallium ions.

5. The method of any preceding claim, wherein the magnetic material is formed on a substrate.

6. The method of claim 1, wherein the ion bombardment is performed using an unfocussed ion beam.

7. The method of claim 1, wherein the ion bombardment is performed using a focussed ion beam.

8. The method of claim 1, further comprising applying a mask to the surface layer to prevent the creation of areas of altered magnetisation outside of a desired area of the magnetic material.

9. The method of claim 1, wherein altering the magnetisation of an area within the magnetic material comprises destroying the magnetisation.

10. The method of claim 1, wherein the surface layer atoms displaced into the magnetic material cause poisoning of the magnetic material.

11. The method of claim 1, wherein the magnetic device further comprises a second thin film magnetic layer and a thin film inter-layer sandwiched between the magnetic layer and the substrate.

12. The method of claim 1, wherein the magnetic device is one of a magnetic memory and a magnetic field sensor

13. A magnetic device manufactured using a method comprising: bombarding a surface layer covering a thin film layer of magnetic material with ions to displace atoms from the surface layer into the magnetic material to alter the magnetisation of an area within the magnetic material.

14. A magnetic device comprising a thin film magnetic layer on a substrate, the magnetic layer having a surface layer formed thereupon and having regions therein where magnetisation of the magnetic layer has been altered by atoms moved into the magnetic layer from the surface layer.

15. The magnetic device of claim 14, wherein at least one region has destroyed magnetisation.

16. The magnetic device of claim 14, wherein at least one region has an altered anisotropy.

17. The magnetic device of claim 14, wherein at least one region has an altered coercivity.

18. The magnetic device of claim 14, further comprising a second thin film magnetic layer and an inter-layer sandwiched between the magnetic layer and the substrate.
